(19) United States
(12) Patent Application Publication
(10) Pub. No.: US 2009/0050972 A1
(43) Pub. Date: Feb. 26, 2009

(54) Strained Semiconductor Device and Method of Making Same

(76) Inventors: Richard Lindsay, Fishkill, NY (US); Shyue Seng Tan, Singapore (SG); Joo-Chan Kim, Suwon-city (KR); Jun Jung Kim, Paju-City (KR); Hyung-Yoon Choi, Seongnam-Si (KR); Chung Woh Lai, Singapore (SG); Johnny Widodo, Singapore (SG)

Correspondence Address: SLATER & MATSIL LLP, 17950 PRESTON ROAD, SUITE 1000, DALLAS, TX, 75252, US

(21) Appl. No.: 11/841,516

(22) Filed: Aug. 20, 2007

(51) Int. Cl. H01L 21/768; H01L 23/48; H01L 21/336; H01L 29/78

(52) U.S. Cl. 257/368; 257/774; 438/675; 438/303; 257/E21.585; 257/E21.409; 257/E23.011; 257/E29.255

(57) ABSTRACT

A method of making a semiconductor device is disclosed. A semiconductor body, a gate electrode and source/drain regions are provided. A liner is provided that covers the gate electrode and the source/drain regions. Silicide regions are formed on the semiconductor device by etching a contact hole through the liner.

### TECHNICAL FIELD

This invention relates generally to semiconductor devices and methods, and more particularly to devices and methods for modulating stress in transistors in order to improve performance.

### BACKGROUND

Semiconductor devices are used in a large number of electronic devices, such as computers, cell phones and others. One of the goals of the semiconductor industry is to continue shrinking the size and increasing the speed of individual devices. Enhancing the mobility of carriers in the semiconductor device is one way of improving device speed.

One technique to improve carrier mobility is to strain (i.e., distort) the semiconductor crystal lattice near the charge-carrier channel region. Transistors built on strained silicon, for example, have greater charge-carrier mobility than those fabricated using conventional substrates.

One technique to strain silicon is to provide a layer of relaxed germanium or silicon germanium. A thin layer of silicon may be grown over the germanium-containing layer. Since the germanium crystal lattice is larger than the silicon, the germanium-containing layer creates a lattice mismatch stress in adjacent layers. Strained channel transistors may then be formed in the strained silicon layer.

Another technique is to provide a stress layer over the transistor. Variants of stress layers can be used for mobility and performance boost of devices. For example, stress can be provided by a contact etch stop layer (CESL), single layers, dual layers, stress memory transfer layers and STI stress liners. Most of these techniques use nitride layers to provide tensile and compressive stresses; however, other materials can be used in other applications, e.g., HDP oxide layers. The channel stress imparted from these layers is a function of their material properties and layer thickness. However, the thickness of the CESL is limited by the technology's design limitations.

ULSI device scaling demands ever increasing levels of channel strain. One of the challenges of strained silicon technology is the need to maintain reasonable levels of device yield and reliability of various elements while increasing strain. For example, increased strain may lead to crystal defects such as dislocations. Such defects may be decorated with silicides or dopants and form unwanted and in some cases fatal leakage paths in the device. Similarly, processes that increase strain may deteriorate other elements. For example, introduction of a thermal anneal after the deposition of the inter layer dielectric (sometimes called pre-metal dielectric) layer may increase the stress in the semiconductor body. However such anneals can severely degrade the silicide contacts and hence result in degraded devices contrary to expectation.

### SUMMARY OF THE INVENTION

In one embodiment of the present invention, a semiconductor device includes an active area disposed in a semiconductor body. A liner is disposed over at least a portion of the active area and a contact hole is etched through the liner to the active region. A contact material layer with a thickness on the active region is formed through the contact hole.

The foregoing has outlined rather broadly features of the present invention. Additional features of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b illustrate a transistor device fabricated using concepts of the present invention;

FIGS. 2a-2h illustrate cross-sectional views of a first embodiment process;

FIG. 3 which includes FIG. 3a and FIG. 3b, illustrates implementations of the first embodiment process;

FIGS. 4a-4c illustrate cross-sectional views of a second embodiment process; and

FIG. 5 illustrates a flow diagram of one implementation of the second embodiment process.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of preferred embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

The invention will now be described with respect to preferred embodiments in a specific context, namely a method for improving carrier mobility in a metal oxide semiconductor (MOS) device. Concepts of the invention can also be applied, however, to other electronic devices. As but one example, bipolar transistors (or BiCMOS) can utilize concepts of the present invention.

In preferred embodiments, the present invention provides a method for making a semiconductor device. A liner, for example, a stress-inducing liner, is deposited over the active regions of a semiconductor body. The semiconductor device is annealed to increase the stress in the liner, while maintaining the performance, yield and reliability of the electronic component. A contact hole is made to the active regions by etching through the liner. A metal is filled in the contact hole and a contact region is formed in the active regions.

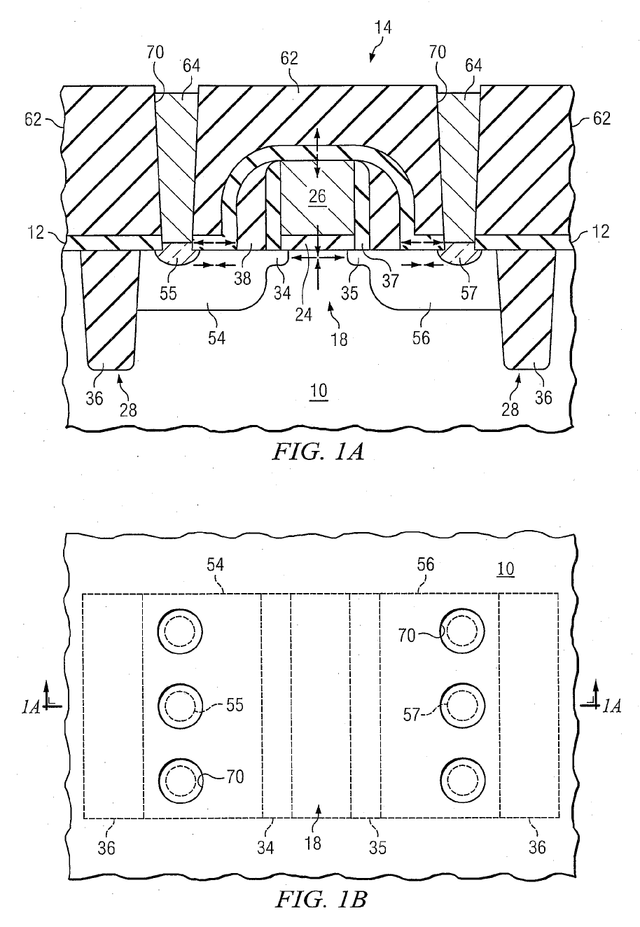

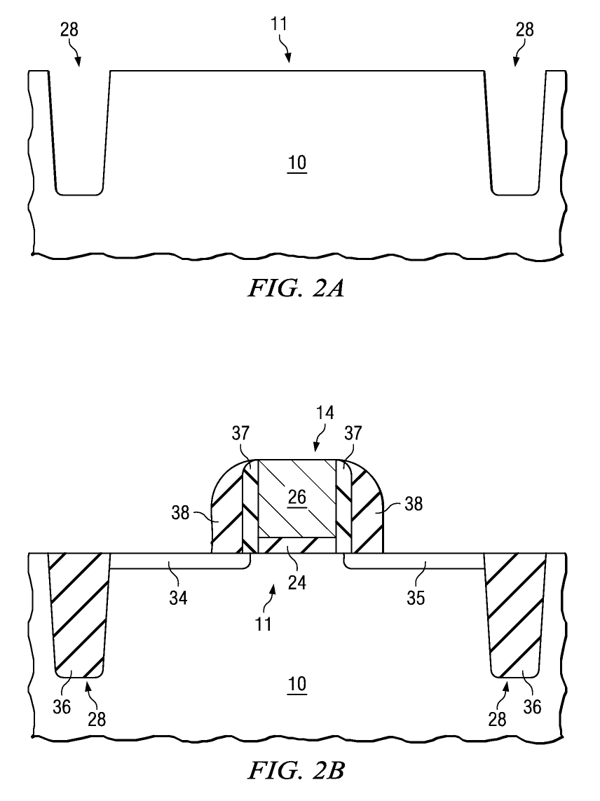

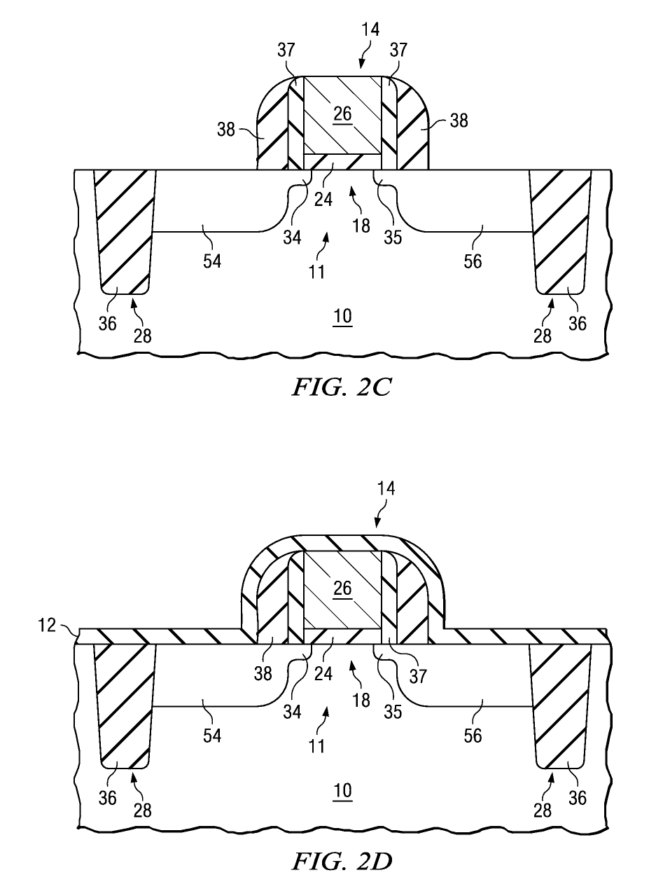

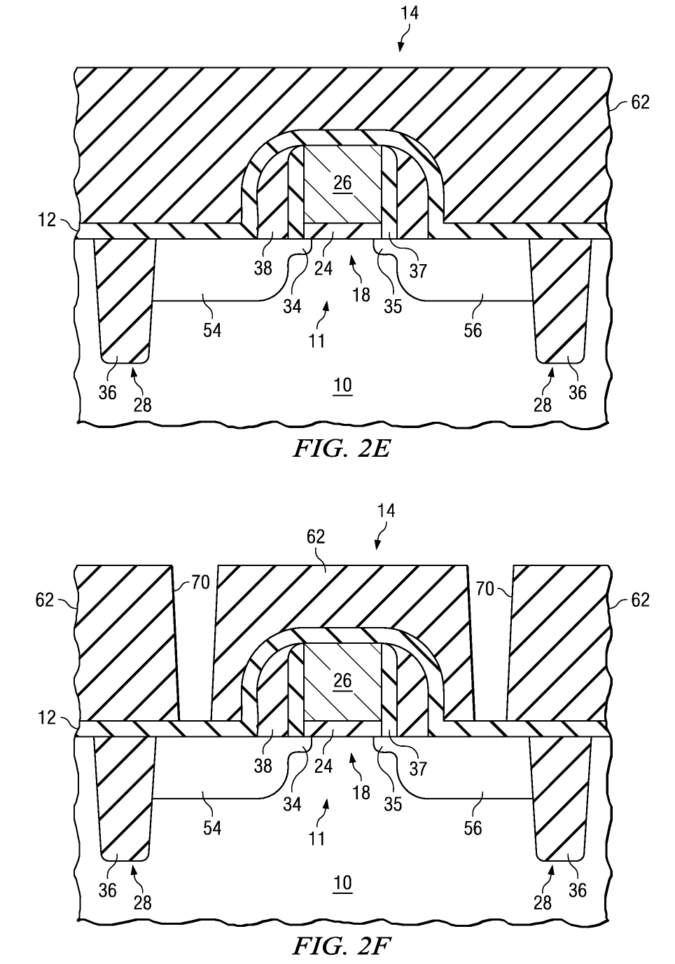

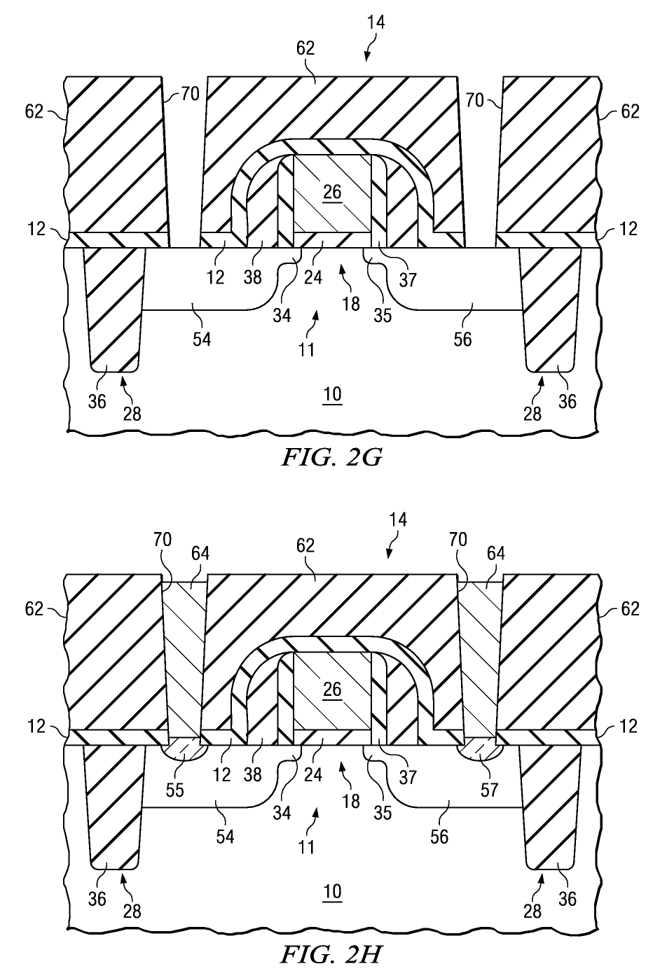

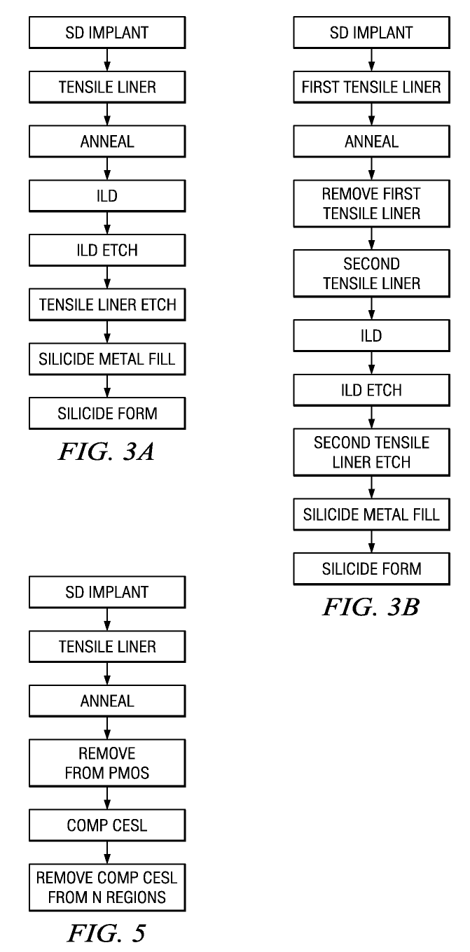

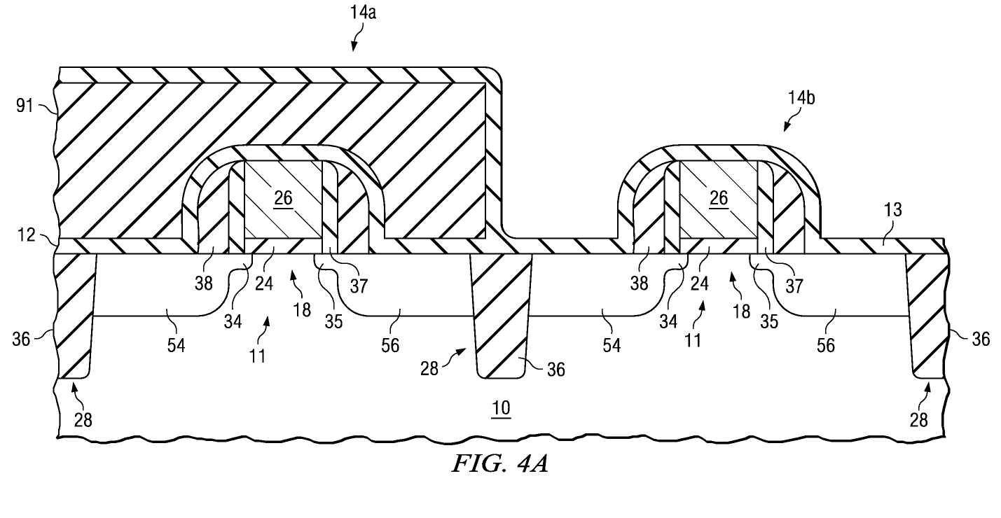

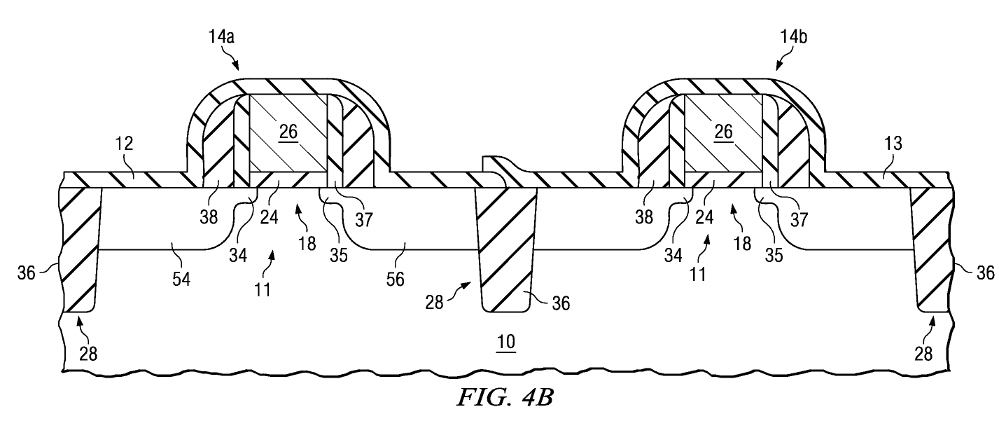

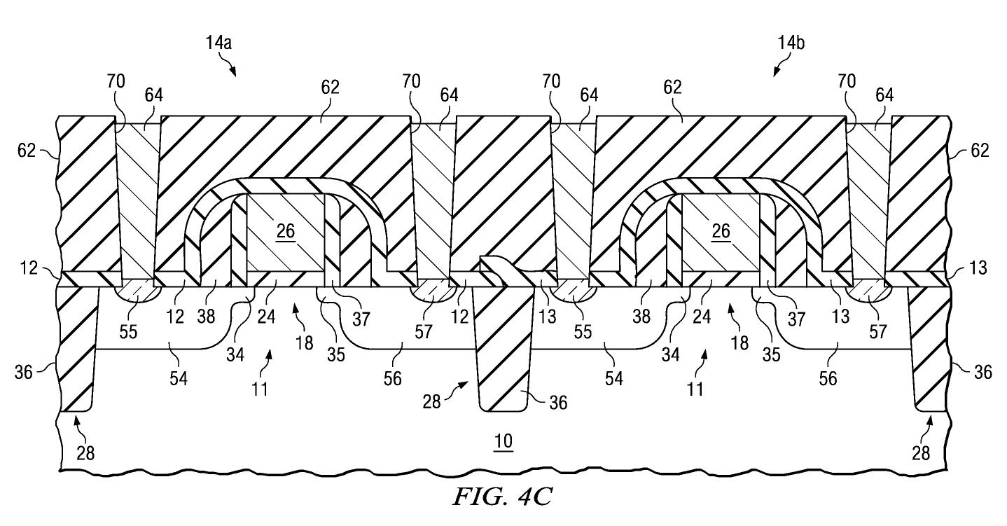

An exemplary transistor device is shown in FIG. 1 and various methods for the formation of transistor devices using these concepts will then be described with respect to the cross-sectional views of FIGS. 2a-2h and FIGS. 4a-4c and the flow charts of FIGS. 3 and 5.

FIGS. 1a and 1b illustrate an embodiment of the present invention, wherein a transistor device 14 is formed in the semiconductor body 10. In particular, silicided regions are formed after the deposition of contact etch stop liners. Using such an approach, the silicide material can be independently tailored. For example, if the volume of the silicided regions can thus be reduced without a significant penalty on the device contact resistance, many problems associated with silicide formation can be avoided. As an example, yield killers such as silicide pipes or shorts as well shorts along the isolation sidewall can be minimized.

Referring to FIG. 1a, the transistor 14 includes a channel region 18 disposed in the semiconductor body 10. Shallow trench isolation 36 comprising isolation trenches 28 filled with an insulating oxide define the transistor regions. A gate dielectric 24 overlies the channel region 18 and a gate electrode 26 overlies the gate dielectric 24. A source extension region 34 and a drain extension region 35 are disposed in the semiconductor body 10 and spaced from each other by the channel region 18. A source region 54 and a drain region 56 are disposed in the semiconductor body 10 and connect to the extension regions 34 and 35. The transistor 14 also includes spacers 37 and 38 used in the formation of the source/drain regions 54 and 56 and extension regions 34 and 35. A stress liner 12 overlies the source/drain regions 54 and 56 and the gate electrode 26. In the present example, the stress liner 12 is tensile, whereas it may also be compressive in other cases. The stress from the stress liner 12 is shown in FIG. 1a as arrows. Arrows facing outward represent tensile stress, whereas arrows facing together represent compressive stress. The tensile stress liner 12 applies a lateral tensile stress in the channel region 18. In one example, the stress liner 12 is a tensile stress liner and the source region 54 and the drain region 56 are n+ regions (and the transistor is therefore an n-channel transistor). In another example, the stress liner 12 is a compressive stress layer and p+ source region 54 and drain region 56 form a p-channel transistor. While illustrated as being a stress liner 12, it is understood that concepts of the invention apply equally to embodiments where the liner 12 creates no stress.

An interlayer dielectric (ILD) 62 covers the stress liner 12. Silicide regions 55 and 57 are formed in the source and drain regions (54 and 56) locally around a contact hole 70 formed in the ILD 62 and the stress liner 12. The source/drain electrodes 64 are formed through the contact holes 70.

FIG. 1b illustrates a top cross section of the upper surface of the semiconductor body 10. The silicide regions 55 and 57 are formed only along the contact holes 70 in the source drain regions 54 and 56 of the transistor 14. The transistor 14 is sandwiched between the isolation regions 36. The source and drain extension regions 34 and 35 space out the channel region 18. The top cross section of the contact hole 70 on the source and drain regions 34 and 35 may be of any suitable shape. In the present embodiment, a circular contact hole 70 is shown. In other examples, it may also be a triangle, a quadrilateral (such as a square, a diamond, a rectangle, or a trapezoid), an oval, an ellipse, any other polygon or any non linear shape. Similarly, the current embodiment shows three contacts made onto the active source/drain regions 54 and 56. However, any suitable number of contacts can be present.

In other embodiments, other semiconductor devices and elements can be fabricated beneath the stress liner 12. For example, if the source/drain regions 54 and 56 are formed with opposite polarities, the transistor 14 can be operated as a diode. In another example, the source/drain regions 54 and 56 can be used as contacts to one plate of a capacitor while the gate electrode 26 is used as another gate of a capacitor. This capacitor could be used, for example, as a decoupling capacitor between supply lines (e.g., V_{DD} and ground) on a semiconductor chip.

FIGS. 2a-2h provide cross-sectional diagrams illustrating a first embodiment method of forming a transistor of the present invention and FIG. 3 illustrates an associated flow diagram of one implementation of the process. A second embodiment will then be described with respect to the cross-sectional views of FIG. 4 and the associated flow diagram of FIG. 5. While certain details may be explained with respect to only one of the embodiments, it is understood that these details can also apply to other ones of the embodiments.

Referring first to FIG. 2a and the flow chart of FIG. 3a, a semiconductor body 10 is provided. In the preferred embodiment, the semiconductor body 10 is a silicon wafer. Some examples of the semiconductor body 10 are a bulk mono-crystalline silicon substrate (or a layer grown thereon or otherwise formed therein), a layer of {110} silicon on a {100} silicon wafer, a layer of a silicon-on-insulator (SOI) wafer, or a layer of a germanium-on-insulator (GeOI) wafer. In other embodiments, other semiconductors such as silicon germanium, germanium, gallium arsenide, indium arsenide, indium gallium arsenide, indium antimonide, or others can be used with the wafer.

In the first embodiment, isolation trenches 28 are formed in the semiconductor body 10. Conventional techniques may be used to form the isolation trenches 28. For example, a hard mask layer (not shown here), such as silicon nitride, can be formed over the semiconductor body 10 and patterned to expose the isolation areas 28. The exposed portions of the semiconductor body 10 can then be etched to the appropriate depth, which is typically between about 200 nm and about 400 nm. The isolation trenches 28 define active area 11, in which integrated circuit components can be formed.

Referring now to FIG. 2b, the isolation trenches 28 are filled with an isolating material forming shallow trench isolation 36. For example, exposed silicon surfaces can be thermally oxidized to form a thin oxide layer. The isolation trenches 28 can then be lined with a first material such as a nitride layer (e.g., Si₃N₄). The isolation trenches 28 can then be filled with a second material, such as an oxide. For example, a high density plasma (HDP) can be performed, with the resulting fill material being referred to as HDP oxide. In other embodiments, other trench filling processes can be used. For example, while the trench is typically lined, this step can be avoided with other fill materials (e.g., HARP™).

As also shown in FIG. 2b, gate stack is formed. A gate dielectric 24 is deposited over exposed portions of the semiconductor body 10. In one embodiment, the gate dielectric 24 comprises an oxide (e.g., SiO₂), a nitride (e.g., Si₃N₄), or a combination of oxide and nitride (e.g., SiON, or an oxide-nitride-oxide sequence). In other embodiments, a high-k dielectric material having a dielectric constant of about 5.0 or greater is used as the gate dielectric 24. Suitable high-k materials include HfO₂, HfSiOₓ, Al₂O₃, ZrO₂, ZrSiOₓ, Ta₂O₅, La₂O₃, nitrides thereof, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, combinations thereof, or combinations thereof with SiO₂, as examples. Alternatively, the gate dielectric 24 can comprise other high-k insulating materials or other dielectric materials. As implied above, the gate dielectric 24 may comprise a single layer of material, or alternatively, the gate dielectric 24 may comprise two or more layers.

The gate dielectric 24 may be deposited by chemical vapor deposition (CVD), atomic layer deposition (ALD), metal organic chemical vapor deposition (MOCVD), physical vapor deposition (PVD), or jet vapor deposition (JVD), as examples. In other embodiments, the gate dielectric 24 may be deposited using other suitable deposition techniques. The gate dielectric 24 preferably comprises a thickness of about 10 Å to about 60 Å in one embodiment, although alternatively, the gate dielectric 24 may comprise other dimensions.

In the illustrated embodiment, the same dielectric layer would be used to form the gate dielectric 24 for both the p-channel and n-channel transistors. This feature is not however required. In alternate embodiments, the p-channel transistors and the n-channel transistors could each have different gate dielectrics.

The gate electrode 26 is formed over the gate dielectric 24. The gate electrode 26 preferably comprises a semiconductor material, such as polysilicon or amorphous silicon, although alternatively, other semiconductor materials may be used for the gate electrode 26. In other embodiments, the gate electrode 26 may comprise TiN, TiC, HfN, TaN, TaC, W, Al, Ru, RuTa, TaSiN, NiSiₓ, CoSiₓ, TiSiₓ, Ir, Y, YbSiₓ, ErSiₓ, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, a partially silicided gate material, a fully silicided gate material (FUSI), other metals, and/or combinations thereof, as examples. In one embodiment, the gate electrode 26 comprises a doped polysilicon layer underlying a silicide layer (e.g., titanium silicide, nickel silicide, tantalum silicide, cobalt silicide, or platinum silicide).

The gate electrode 26 may comprise a plurality of stacked gate materials, such as a metal underlayer with a polysilicon cap layer disposed over the metal underlayer. A gate electrode 26 having a thickness of between about 400 Å to 2000 Å may be deposited using CVD, PVD, ALD, or other deposition techniques.

P-channel and n-channel transistors preferably include gate electrodes 26 formed from the same layers. If the gate electrodes 26 include a semiconductor, the semiconductor can be doped differently for the p-channel transistors and the n-channel transistors. In other embodiments, different types of transistors can include gates of different materials and/or thicknesses.

The gate layer (and optionally the gate dielectric layer) is patterned and etched using known photolithography techniques to create the gate electrode 26 of the proper pattern. After formation of the gate electrode 26, a thin layer of spacers 37 are formed. The spacers 37 are formed from an insulating material such as an oxide and/or a nitride, and can be formed on the sidewalls of the gate electrode 26. The spacers 37 are typically formed by the deposition of a conformal layer followed by an anisotropic etch. The process can be repeated for multiple layers, as desired. In some cases, if the gate electrode 26 is polysilicon, the thin spacers 37 may be formed by poly oxidation.

The source/drain extension regions (34 and 35) can be implanted using this structure (the gate electrode 26 and the thin spacer 37) as a mask. Other implants (e.g., pocket implants, halo implants or double diffused regions) can also be performed as desired. The extension implants also define the channel region 18 of the transistor 14. If a p-type transistor is to be formed, a p-type ion implant along with an n-type halo implant is used to form the source/drain extension regions 34 and 35. For example, boron ions can be implanted with a dose of about 1×10¹⁴ cm⁻² to about 3×10¹⁵ cm⁻² at a implant energy between about 0.1 keV to about 1 keV. In other embodiments, other materials, such as BF₂ or cluster boron can be implanted. In some cases, the n-type halo implant is arsenic with a dose of about 1×10¹³ cm⁻² to about 2×10¹⁴ cm⁻² at an implant energy between about 10 keV to about 100 keV. If an n-type transistor is to be formed, an n-type ion implant along with a p-type halo implant is used to form the source 34 and drain 35 extension regions. In the preferred embodiment, arsenic ions are implanted into the source/drain extension regions 34/35. For example, arsenic ions can be implanted with a dose of about 1×10¹⁴ cm⁻² to about 3×10¹⁵ cm⁻² and an implant energy between about 0.5 keV and about 5 keV. In other embodiments, other materials, such as P and Sb can be implanted. In some cases, the p-type halo implant is boron with a dose of about 1×10¹³ cm⁻¹ to about 2×10¹⁴ cm⁻² at an implant energy between about 1 keV and about 10 keV. In some embodiments, the extension implants can also contain additional implants such as for amorphization or reducing diffusion. Some examples of such implants include silicon, germanium, fluorine, carbon, nitrogen, and/or combinations thereof. Source and drain spacers 38 can be formed on the sidewalls of the existing thin spacer 37. FIG. 2b shows the device after this step.

FIG. 2c shows the device after it has been exposed to an ion implant step which forms the source/drain regions 54/56 of the transistor 14. Similar to the formation of the extension regions 34 and 35, if a p-type transistor is to be formed, a p-type ion implant is used to form the heavily doped source/drain regions 54/56. For example, boron ions can be implanted with a dose of about 1×10¹⁵ cm⁻² to about 3×10¹⁵ cm⁻² at an implant energy between about 1 keV and about 5 keV. In other embodiments, other materials, such as BF₂, molecular boron, or cluster boron can be implanted. If an n-type transistor is to be formed, an n-type ion implant is used to form the heavily doped source/drain regions 54/56. In the preferred embodiment, arsenic ions are implanted into the source/drain regions 54/56. For example, arsenic ions can be implanted with a dose of about 1×10¹⁵ cm⁻² to about 5×10¹⁵ cm⁻² and an implant energy between about 5 keV and about 30 keV. In other embodiments, other materials, such as P and Sb can be implanted. In some embodiments, fluorine, carbon, nitrogen, silicon, germanium or combinations of these materials are co-implanted along with the source drain implants.

In FIG. 2d, a stress liner 12 is deposited over the surface of transistor 14. The liner 12 is preferably a stress-inducing liner. In one particular example, the stress liner 12 is a stress inducing contact etch stop layer (CESL). For example, a nitride film (e.g., silicon nitride) is deposited in such a way as to create a stress between the stress liner 12 and the underlying semiconductor body 10. The stress liner 12 may be deposited in a single step or in multiple steps and may consist of either a single material or a stack of different materials. In the preferred embodiment, the stress liner 12 is a tensile silicon nitride. However, in other embodiments the stress liner 12 may have other types of stress or no stress. In some embodiments, the source/drain spacers 38 may be either partially or fully removed to enable the formation of a thicker CESL stress liner 12 and hence transfer more stress to the channel region 18. The stress liner 12 is a blanket film across the semiconductor body 10 in the current embodiment. However, in some instances, it may also be selectively removed from some of the devices.

A source/drain anneal follows the deposition of the stress liner 12. This is done to remove the implantation damage and form the junctions. For a silicon nitride liner, typically the number of Si—H to Si—N bonds influences the state of stress in the stress liner 12. For example, the lower Si—H to Si—N ratio, the more tensile the stress. Annealing lowers this SiH to SiN ratio and hence increases the tensile stress in the liner 12. This translates to a higher stress in the channel region 18. This anneal step is preferably performed at a temperature between about 700° C. and about 1200° C., for a time between about 0.1 ms and about 1 s. For example, a rapid thermal anneal (RTA) can be performed at a temperature of 1090° C. for 0.1 s.

Although the liner 12 in the preferred embodiment is a single layer of nitride, the stress liner 12 may also be a multilayer film or other dielectric, such as SiC. For example, the stress liner 12 may be a nitride-oxide-nitride stack. In a particular instance of such an embodiment, the outer layers of the nitride-oxide-nitride stack may be etched after the source drain anneal. This helps to maximize the stress in the channel region 18 while maintaining the appropriate spacing for landing the contact holes 70.

Although, in the current embodiment, the source/drain anneal follows the formation of the stress liner 12, in some embodiments, the stress liner 12 may be deposited after the source/drain anneal.

Further, in an alternate embodiment (as shown in flow chart of FIG. 3b), the stress liner 12 may be removed after the source/drain anneal. The process also called stress memorization memorizes the stress from the stress liner 12. A second stress liner may be deposited after the removal of the stress liner 12. The second liner may be thinner than the stress liner 12 and optimized, for example, for contact formation. An optional anneal may be performed after the deposition of the second liner to increase the stress of the liner and hence the total channel stress in the device.

Similarly, in a different embodiment, the first liner and removal of the first liner in the flow chart of FIG. 3b may be skipped. The tensile liner in such an embodiment may be deposited after the source/drain anneal.

Referring now to FIG. 2e, an interlayer dielectric (ILD) layer 62 is then formed over the stress liner 12. Suitable ILD layers include materials such as doped glass (BPSG, PSG, BSG), organo silicate glass (OSG), fluorinated silicate glass (FSG), spun-on-glass (SOG), silicon nitride, and plasma enhanced tetraethyloxysilane (TEOS), as examples.

In FIG. 2f, in regions where the contact is to be made, the ILD layer 62 is etched down to the stress liner 12. In one exemplary process, photoresist (not shown) is deposited and patterned to mask off the non-exposed regions to the etch. The ILD layer 62 is then etched down to the stress liner 12 using standard etch techniques. In this step, the ILD layer 62 etches away at a faster rate than the stress liner 12. Once the etch is complete, the photoresist may be removed. A second etch completes the formation of contact holes 70 as shown in FIGS. 2f and 2g. This time, the stress liner 12 is etched to expose the source/drain regions 54/56 using the ILD layer 62 as a mask.

Referring to FIG. 2h, a suitable silicide metal is first filled into the contact hole 70 and over the ILD layer 62. The semiconductor body 10 is then heated to about 500° C. to about 700° C. The exposed part of the source/drain regions 54/56 react with the filled silicide metal to form a single layer of metal silicide 55 and 57. Any un-reacted silicide metal may be removed. In the preferred embodiment, the silicide metal is nickel platinum, but could also be nickel, cobalt, copper, molybdenum, titanium, tantalum, tungsten, ytterbium, erbium, zirconium, platinum, or combinations thereof. The preferred anneal temperature is about 500° C. but any other suitable anneal temperature can be used. The silicidation of the source/drain regions 54/56 results in formation of silicide regions (55 and 57) with a thickness of about 50 Å to about 300 Å. Due to volume expansion during silicide formation, the silicide regions (55 and 57) may extend into a part of the contact hole 70. After the silicide formation, the contact hole is filled with a suitable metal to form the source/drain electrodes 64. If the gate electrode is polysilicon, the liner 12 over the gate electrode 26 may also be similarly etched and filled with a metal and silicided. This would again form a gate silicide contact (not shown) similar to the source/drain contact.

In the present embodiment, the contact material is a silicide as the source/drain regions 54/56 comprise silicon. However in some cases, the source/drain regions 54/56 may also be other materials such as SiC, SiGe, Ge, GaAs, InSb. In such cases, a suitable contact material can be selected that provides low contact resistance. For example, if embedded SiGe or SiGeC is used for the source/drain regions 54/56, the contact material may be a combination of silicide and germanide.

Further processing continues as in a typical integrated chip manufacturing process. For example, typically, gate electrode contacts are formed through the ILD layer 62 (not shown). Metallization layers that interconnect the various components are also included in the chip, but are not illustrated herein for the purpose of simplicity.

A second embodiment will now be described with reference to the cross-sectional diagrams of FIGS. 4a-4c and the flow diagram of FIG. 5. In some cases, it is desirable to create different types of stress in different types of transistors. It is well known in the art that lateral tensile stress improves electron mobility (or improves n-channel transistors), but degrades hole mobility (or p-channel transistors). For example, as discussed above, a tensile stress liner can create a lateral tensile stress for an n-channel transistor while a compressive liner causes a lateral compressive stress for a p-channel transistor. The nature of the enhancement or degradation depends on the channel orientation and crystal surface of the substrate material. For example if the substrate is {100} silicon, p-channel transistors with current transport direction along <110> direction are enhanced by a compressive stress, whereas the same transistors along <100> are relatively unchanged. Consequently, to maximize the impact of stress on n-channel and p-channel transistors for a {100} silicon substrate, both transistors are aligned along <110> directions. Further, the tensile stress liner 12 may be replaced with a new compressive stress liner over the p-channel device regions. In this manner, both p-channel and n-channel devices may be separately optimized.

In this embodiment, the process begins with the semiconductor body 10, a gate dielectric 24, a gate electrode 26, and source/drain regions 54/56, as discussed above and shown in FIGS. 2a-2d. Using these process steps, the active transistors of both n-channel transistors 14a and p-channel transistors 14b are first fabricated on the semiconductor body 10. This is illustrated in FIG. 4a and shows a particular instance, when the n-channel transistors 14a and p-channel transistors 14b share an isolation region 36. A mask layer 91 is formed over the semiconductor body 10, and patterned to expose the stress liner 12 over the p-channel transistors 14b. The exposed stress liner 12 is etched off from the p-channel transistors 14b. An alternate stress liner 13 is deposited on top of the p-channel transistors 14b. In preferred embodiments, the alternate stress liner 13 is a compressive stressed liner.

Referring next to FIG. 4b, the n-channel and p-channel transistors 14a and 14b are again masked and patterned to expose the n-channel transistors 14a. The alternate stress liner 13 is now removed from the n-channel transistors 14a, and followed by removal of all the mask layers. When n-channel transistors 14a and p-channel transistors 14b are adjacent to each other (as in this embodiment), the overlap of the stress liner 12 and the alternate stress liner 13 is carefully optimized to maximize gain for each type of transistor. Further processing continues as shown in FIGS. 2e-2h. The final n-channel transistor 14a and p-channel transistor 14b thus fabricated are shown in FIG. 4c.

It will also be readily understood by those skilled in the art that materials and methods may be varied while remaining within the scope of the present invention. It is also appreciated that the present invention provides many applicable inventive concepts other than the specific contexts used to illustrate preferred embodiments. Accordingly, the appended claims are intended to include within their scope such processes, machines, manufacture, compositions of matter, means, methods, or steps.

What is claimed is:

1. A semiconductor device comprising:
an active area disposed in a semiconductor body;
a liner over at least a portion of the active area;
a contact hole etched through the liner to the active region; and
a contact material layer with a thickness on the active region, the contact material layer formed through the contact hole

2. The semiconductor device of claim 1, wherein the liner comprises a stress inducing liner.

3. The semiconductor device of claim 2, wherein the stress inducing liner comprises a contact etch stop layer.

4. The semiconductor device of claim 1, wherein the contact hole comprises a square-shaped contact hole

5. The semiconductor device of claim 1, wherein the contact hole comprises a round contact hole.

6. The semiconductor device of claim 1, wherein the contact hole comprises an oval-shaped contact hole.

7. The semiconductor device of claim 1, wherein the contact material layer comprises silicide or germanide.

8. The semiconductor device of claim 1, wherein the contact material layer comprises materials selected from the group consisting of nickel silicide, platinum silicide, nickel germanide, platinum germanide, yerbium silicide, yerbium germanide, erbium silicide, erbium germanide, cobalt silicide, titanium silicide, tantalum silicide, molybdenum, tungsten and combinations thereof.

9. The semiconductor device of claim 1, wherein the thickness of the contact material layer is between about 80 Å and about 300 Å.

10. A semiconductor device comprising:
an active area disposed in a semiconductor body;
a shallow trench isolation region surrounding the active area;
a gate formed over a portion of the active area;
source/drain regions formed in the active area adjacent to the gate;
a liner formed over the gate, over the active area adjacent to the gate, and at least a part of the shallow trench isolation region;
a contact hole etched through the liner to the active area; and
a contact material on the active area formed through the contact hole.

11. The semiconductor device of claim 10, wherein the liner comprises a stress inducing liner.

12. The semiconductor device of claim 10, further comprising an interlevel dielectric layer over the liner, wherein the contact hole extends into the interlevel dielectric layer.

13. The semiconductor device of claim 10, wherein the semiconductor device is an n-channel transistor.

14. The semiconductor device of claim 10, wherein the semiconductor device is a p-channel transistor.

15. The semiconductor device of claim 10, wherein the contact material comprises silicide or germanide.

16. A method of making a semiconductor device, the method comprising:
providing a semiconductor body;
providing an active area in the semiconductor body;
depositing a liner over at least a part of the active area;
forming a contact hole in the liner thereby exposing a part of the active area through the contact hole;
filling the contact hole with a metal; and
forming a contact material on the active area through the contact hole, the contact material being formed using the metal filling the contact hole.

17. The method of claim 16, wherein the liner comprises a stress inducing liner.

18. The method of claim 17, wherein the stress inducing liner comprises a contact etch stop layer.

19. The method of claim 16, further comprising annealing the deposited liner prior to the contact material formation.

20. The method of claim 16, wherein the contact material comprises silicide or germanide.

21. The method of claim 16, wherein the contact material comprises materials selected from the group consisting of nickel silicide, platinum silicide, nickel germanide, platinum germanide, yerbium silicide, yerbium germanide, erbium silicide, erbium germanide, cobalt silicide, titanium silicide, tantalum silicide, molybdenum, tungsten and combinations thereof.

22. The method of claim 16, wherein the metal comprises metals selected from the group consisting of nickel, cobalt, copper, molybdenum, titanium, tantalum, tungsten, ytterbium, erbium, zirconium, platinum, or combinations thereof.

23. The method of claim 16, wherein the contact hole is formed to expose a source/drain region of a transistor formed in the active area.

24. The method of claim 16, wherein forming a contact hole comprises performing an etch process that etches the liner selectively with respect to the active area.

25. A method of making a semiconductor device, the method comprising:
forming at least one active area in a semiconductor body;
forming a gate stack over a portion of the active area;
forming sidewall spacers adjacent sidewalls of the gate stack;
implanting source/drain regions in the active area adjacent the gate stack;
depositing a liner over the gate stack, the sidewall spacers, and the implanted source/drain regions;
annealing the semiconductor device;
etching a part of the liner to form a contact hole, wherein the etching exposes a part of the active area through the contact hole;
filling the contact hole with a metal; and
forming contact material regions over the source/drain regions through the contact hole.

26. The method of claim 25, wherein the annealing increases stress in the liner.

27. The method of claim 25, wherein the contact material regions comprise silicide or germanide.

28. The method of claim 25, wherein the contact material regions comprise materials selected from the group consisting of nickel silicide, platinum silicide, nickel germanide, platinum germanide, yerbium silicide, yerbium germanide, erbium silicide, erbium germanide, cobalt silicide, titanium silicide, tantalum silicide, molybdenum, tungsten and combinations thereof.

29. The method of claim 25, wherein the metal comprises metals selected from the group consisting of nickel, cobalt, copper, molybdenum, titanium, tantalum, tungsten, ytterbium, erbium, zirconium, platinum, or combinations thereof.
